(19) United States
(12) Patent Application Publication
(10) Pub. No.: US 2005/0054206 A1
(43) Pub. Date: Mar. 10, 2005

(54) Etching method and recipe for forming high aspect ratio contact hole

(75) Inventors: Tse-Yao Huang, Taipei (TW); Chang-Ming Wu, Jhonghe City (TW)

Correspondence Address: BACON & THOMAS, PLLC, 625 SLATERS LANE, FOURTH FLOOR, ALEXANDRIA, VA, 22314, US

(73) Assignee: NANYA Technology Corporation, Kueishan (TW)

(21) Appl. No.: 10/653,882

(22) Filed: Sep. 4, 2003

(51) Int. Cl. H01L 21/302; H01L 21/461

(52) U.S. Cl. 438/710

(57) ABSTRACT

Disclosed is an etching method for forming a high aspect ratio contact hole. The plasma gas composition for the etching comprises Ar, a first fluorocarbon, O₂ and a second fluorocarbon, wherein the fluorine-to-carbon ratio of the second fluorocarbon is higher than that of the first fluorocarbon. The method of the present invention can maintain the profile of the contact hole well, and reduce the accumulation of the etch stop generated during etching.

### BACKGROUND OF THE INVENTION

1.Field of the Invention

This invention relates to an etching technique for semiconductor integrated circuit devices, more specifically, to an etching method for forming a contact hole of high aspect ratio (HAR).

2. Description of the Prior Art

The etching for the contact holes of semiconductor integrated circuit devices plasma etching by means of is usually. In order to satisfy the requirements such as selective ratio, etching efficiency, critical dimension of contact holes, and uniformity for highly compact integrated circuit devices, active ion etching method, which is a combination of physical etch and chemical etch, is generally utilized. The plasma gas composition for the active ion etching method contains Argon gas (Ar), Oxygen gas (O₂) and fluorocarbon (CₓF_{y}).

In the current process for DRAM devices, an etching method for high aspect ratio (HAR) contact holes utilizes Ar/O₂/C₅F₈ gas composition as plasma gas, wherein Ar is used for physical etching, C₅F₈ is used for chemical etching, and O₂ is used for clearing off etch stop generated during the action of C₅F₈. However, this etching method usually makes the bottom surface of the formed contact hole uneven, that is, on a bowing phenomenon may appear the bottom surface of the contact hole.

With reference to FIG. 1, which shows a portion of a DRAM element to be formed with contact holes, reference number 10 is a semiconductor substrate, and a pad oxide layer 11 and a pad nitride layer 12 are deposited on the substrate 10. An oxide layer including a boro-silicate glass (BSG) layer 13 and an undoped silicate glass layer (USG) 14 is formed on the pad nitride layer 12. Finally, a polymer hard mask (PHM) 15 of a predetermined pattern is formed on the entire structure. The gaps between the respective portions 151, 152, 153 of the PHM 15 are the locations to be formed with contact holes by plasma etching method.

In this drawing, the dimension of the gap between two portions of the PHM 15, for example, portions 152 and 153, is a, and the distance (hereafter, the pitch) from a side of the portion 152 to the same side of the other portion 153 of the PHM 15 is b, then the critical dimension (CD) of the PHM portion 152 is b-a.

FIG. 2 shows longitudinal profiles of practical contact holes, wherein there is a spacing 25 between two contact holes 21 and 22. In the structure shown in FIG. 2, the pitch (the critical dimension of the distance from one side of the contact hole 21 to the same side of the contact hole 22) is about 220 to 250 nm, the minimum critical dimension of the spacing 25 is about 45 to 75 nm, the maximum critical dimension of the contact hole is about 175 to 180 nm, and the critical dimension of the bottom of the contact hole is about 140 nm.

As described above, the etching method uses Ar/O₂/C₅F₈ gas composition as plasma gas. However, the proportion of each gas in this composition is hardly adjusted. If the amount of O₂ increases, the etch efficiency is lifted. However, as the amount of O₂ increases, the critical dimension of the spacing 25 between the two contact holes 21 and 22 will sharply lessen, resulting in the deterioration of the longitudinal profiles of the contact holes, even the mergence of the two contact holes 21 and 22. If the amount of O₂ is not sufficient, the contact hole cannot be formed smoothly. The condition is different for C₅F₈. If the concentration of C₅F₈ is not sufficiently high, it is not possible to etch the contact hole to a required depth. If the concentration of C₅F₈ is too high, then undesired etching stop is generated accordingly. As a result, the contact hole has its critical dimension lessened or even fails to be successfully opened.

Therefore, a solution to solve the above problems is necessary. The present invention satisfies such a need.

### SUMMARY OF THE INVENTION

An objective of the present invention is to provide a method for forming high aspect ratio contact holes, which can maintain the good profiles of the contact holes and reduce the accumulation of etching stop generated during etching.

Another objective of the present invention is to provide a plasma gas composition for forming high aspect ratio contact holes. Using this plasma gas composition, the profiles of the contact holes can be well controlled, and the accumulation of etching stop generated during etching can be reduced.

According to an aspect of the present invention, the method for forming high aspect ratio contact holes uses a plasma gas composition comprising a fluorocarbon of high fluorine-to-carbon ratio.

According to another aspect of the present invention, the method for forming high aspect ratio contact holes uses a plasma gas composition comprising a fluorocarbon of high fluorine-to-carbon ratio higher than 8:5.

According to a further aspect of the present invention, the method for forming high aspect ratio contact holes uses a plasma gas composition comprising C₃F₈.

According to an aspect of the present invention, the plasma gas composition for forming high aspect ratio contact holes comprises a fluorocarbon of high fluorine-to-carbon ratio.

According to another aspect of the present invention, the plasma gas composition for forming high aspect ratio contact holes comprises a fluorocarbon of high fluorine-to-carbon ratio higher than 8.5.

According to a further aspect of the present invention, the plasma gas composition for forming high aspect ratio contact holes comprises C₃F₈.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIG. 1 is a sectional schematic diagram showing a portion of a DRAM element to be formed with contact holes; and

FIG. 2 shows the longitudinal profiles of practical contact holes.

### DETIALED DESCRIPTION OF THE PREFERRED EMBODIMENT

The technical contents, objectives and effects achievable disclosed by the present invention will be described in detail as follows.

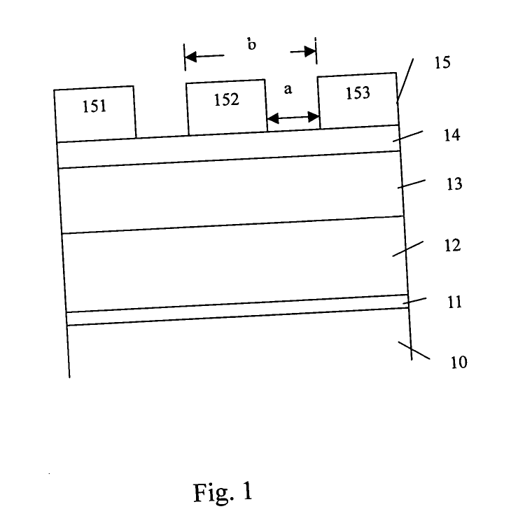

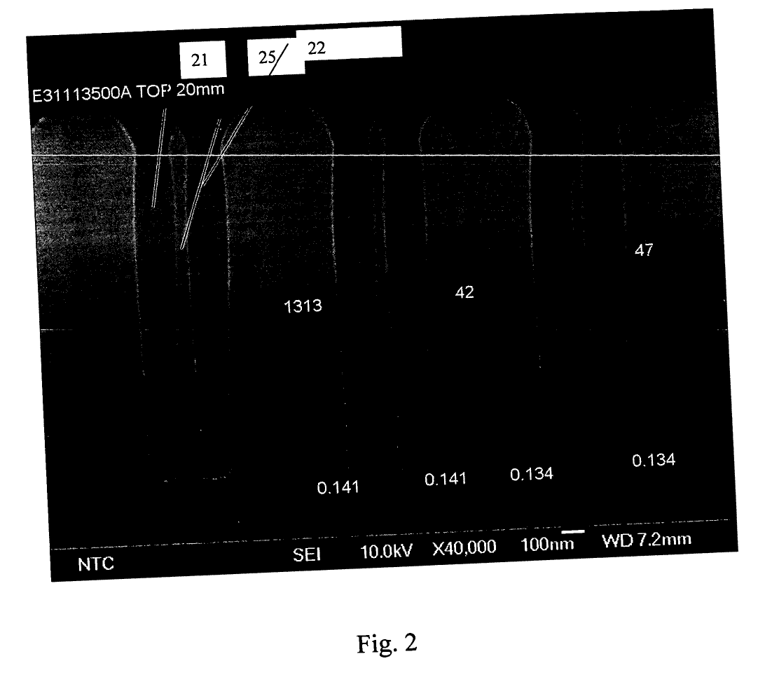

In the manufacturing process for DRAM elements, the manner for forming contact holes is shown in FIG. 1. As described above, after the pad oxide layer 11, pad nitride layer 12, BSG layer 13 and USG layer 14 are sequentially formed on the substrate 10, the polymer hard mask 15 is formed to define the regions to be etched off. Then, etching is performed by using plasma to form contact holes, as shown in FIG. 2.

In accordance with the present invention, the utilized plasma gas composition comprises Argon gas (Ar), Oxygen gas (O₂) and C₅F₈. In addition, the plasma gas composition further comprises another fluorocarbon, of which the etching characteristic is between O₂ and C₅F₈. The fluorine-to-carbon ratio of the additional fluorocarbon is higher than that of C₅F₈. It is obtained through experiments that the addition can be CHF₃, CH₂F₂ or C₃F₈. The experimental data are listed in the following table.

TABLE 1

| | | | Contact | Uniformity | |
|---|---|---|---|---|---|
| | | Uniformity | hole | of contact | |
| Gas | Spacing | of spacing | bottom | hole | |
| composition | min. CD | min. CD | CD | bottom hole | Remarks |
| C₅F₈/O₂/Ar | 42 nm | 27% | 127 nm | 7.5% | Poor uniformity, |
| | | | | | insufficient contact |
| | | | | | hole bottom CD |
| C₅F₈/O₂/Ar/CHF₃ | 41 mm | 6% | 138 nm | 3.5% | Good uniformity, |
| | | | | | generating etching |
| | | | | | stop, contact hole |
| | | | | | bottom CD |
| C₅F₈/O₂/Ar/CH₂F₂ | 57 nm | 4.3% | 136 nm | 4.4% | Good uniformity, |
| | | | | | generating etching |
| | | | | | stop, contact hole |
| | | | | | bottom CD |
| C₅F₈/O₂/Ar/C₃F₈ | 45 nm | 6.8% | 145 nm | 2.4% | Good uniformity, |
| | | | | | large contact hole |
| | | | | | bottom CD large |
| Target | >40 nm | <10% | >145 nm | <7% | |

In the above table, the uniformity is obtained through measuring nine points of the same wafer and calculating the measured values by equation (1):
Uniformity=(((Maximum value−Minimum value)/Average value)/2)×% (1)

As indicated by the data in Table 1, under the condition that plasma gas composition C₅F₈/O₂/Ar is used as a base, when CHF₃ is added, the uniformity is lifted, the critical dimension of the bottom of the contact hole is increased, but not enough. Besides, this composition has weak etching power for wafers, so that additional auxiliary is needed. When CH₂F₂ is added, the opening of the contact hole lessens, the critical dimension of the bottom of the contact hole is increased, but not enough. Furthermore, these two additions still cause accumulation of etching stop, because of the hydrogen contained in the respective two compounds. Accordingly, a preferable selection is pure fluorocarbon.

According to the result of practical implement, the addition is preferably C₃F₈. This fluorocarbon maintains considerable uniformity and significantly increases the critical dimension of the bottom of the contact hole. In addition, the accumulation of etching stop is avoided.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method for forming high aspect ratio contact holes, comprising steps of:
providing a substrate;
forming a pad oxide layer on said substrate;
forming a pad nitride layer on said pad oxide layer;
forming an oxide layer on said pad nitride layer;
forming a mask of a predetermined pattern on said oxide layer; and
forming contact holes by plasma etching, the plasma etching using a plasma composition comprising argon, oxygen, a first fluorocarbon and a second fluorocarbon, the fluorine-to-carbon ratio of said second fluorocarbon being higher than that of the first fluorocarbon.

2. The method as claimed in claim 1, wherein said first fluorocarbon is C₅F₈.

3. The method as claimed in claim 2, wherein the fluorine-to-carbon ratio of said second fluorocarbon is higher than 8:5.

4. The method as claimed in claim 3, wherein said second fluorocarbon is C₃F₈.

5. A method for forming high aspect ratio contact holes, said method using plasma etching to open contact holes, and being characterized in that the plasma etching uses a plasma composition comprising argon, oxygen, a first fluorocarbon and a second fluorocarbon, the fluorine-to-carbon ratio of said second fluorocarbon being higher than that of the first fluorocarbon.

6. The method as claimed in claim 5, wherein said first fluorocarbon is C₅F₈.

7. The method as claimed in claim 6, wherein the fluorine-to-carbon ratio of said second fluorocarbon is higher than 8:5.

8. The method as claimed in claim 7, wherein said second fluorocarbon is C₃F₈.

9. A plasma composition for forming high aspect ration contact holes, comprising argon, oxygen, a first fluorocarbon and a second fluorocarbon, the fluorine-to-carbon ratio of said second fluorocarbon being higher than that of the first fluorocarbon.

10. The composition as claimed in claim 9, wherein said first fluorocarbon is C₅F₈.

11. The composition as claimed in claim 10, wherein the fluorine-to-carbon ratio of said second fluorocarbon is higher than 8:5.

12. The composition as claimed in claim 11, wherein said second fluorocarbon is C₃F₈.
